(19) United States
(12) Patent Application Publication
(10) Pub. No.: US 2025/0218817 A1
(43) Pub. Date: Jul. 3, 2025

(54) SUBSTRATE BONDING APPARATUS

(71) Applicant: Samsung Electronics Co., Ltd., Suwon-si (KR)

(72) Inventors: Eunyoung Ahn, Suwon-si (KR); Chan Hwang, Suwon-si (KR); Bongcheol Kim, Suwon-si (KR); Sangho Yun, Suwon-si (KR)

(21) Appl. No.: 18/989,054

(22) Filed: Dec. 20, 2024

(30) Foreign Application Priority Data
Dec. 27, 2023 (KR) 10-2023-0193182

(51) Int. Cl. H01L 21/67; H01L 21/683

(52) U.S. Cl. CPC H01L 21/67092; H01L 21/67259; H01L 21/6838

(57) ABSTRACT

A substrate bonding apparatus for bonding a first substrate to a second substrate includes a lower bonding chuck configured to support the first substrate, an upper bonding chuck facing the lower bonding chuck and configured to support the second substrate, a gas discharge device provided through the center of the upper bonding chuck and configured to discharge pressurized gas to a top surface of the second substrate, a gas supply unit configured to supply the pressurized gas to the gas discharge device, and a controller configured to control the gas discharge device and the gas supply unit and the controller controls vertical movement of the gas discharge device with respect to the upper bonding chuck, and a flow rate and pressure of the pressurized gas in the gas discharge device.

### CROSS-REFERENCE TO RELATED APPLICATION

This application is based on and claims priority under 35 U.S.C. § 119 to Korean Patent Application No. 10-2023-0193182, filed on Dec. 27, 2023, in the Korean Intellectual Property Office, the disclosure of which is incorporated by reference herein in its entirety.

### BACKGROUND

The inventive concept relates to a substrate bonding apparatus, and more particularly, to a substrate bonding apparatus for bonding two wafers.

Various semiconductor products, including a complementary metal oxide semiconductor (CMOS) image sensor (CIS), high bandwidth memory (HBM), and bonding VNAND, may be manufactured by bonding two wafers to each other. In semiconductor device manufacturing processes, a substrate bonding process may be performed to bond two or more substrates to each other. The substrate bonding process may be performed to improve mounting density of a semiconductor chip in a semiconductor device. The substrate bonding process may be performed by a wafer-to-wafer method in which two wafers are directly bonded to each other without a separate medium. The wafer-to-wafer method may typically be performed by using a bonding device including a bonding chuck supporting wafers and a component pressing wafers.

### SUMMARY

The inventive concept relates to a substrate bonding apparatus performing a high-quality bonding process.

The problems to be solved by the technical idea of the inventive concept are not limited to the above-mentioned problems, and other problems not mentioned will be clearly understood by those skilled in the art from the following description.

According to an aspect of the inventive concept, there is provided a substrate bonding apparatus for bonding a first substrate to a second substrate, including a lower bonding chuck configured to support the first substrate, an upper bonding chuck facing the lower bonding chuck and configured to support the second substrate, a gas discharge device provided through the center of the upper bonding chuck and configured to discharge pressurized gas to a top surface of the second substrate, a gas supply unit configured to supply the pressurized gas to the gas discharge device, and a controller configured to control the gas discharge device and the gas supply unit. The controller controls vertical movement of the gas discharge device with respect to the upper bonding chuck, and a flow rate and pressure of the pressurized gas in the gas discharge device.

According to another aspect of the inventive concept, there is provided a substrate bonding apparatus for bonding a first substrate to a second substrate, including a lower bonding chuck configured to support the first substrate, an upper bonding chuck facing the lower bonding chuck and configured to support the second substrate, a first gas discharge device provided through the center of the upper bonding chuck and configured to discharge pressurized gas to a top surface of the second substrate, a plurality of second gas discharge devices penetrating the upper bonding chuck, apart from the first gas discharge device, and configured to discharge the pressurized gas to a top surface of the second substrate, a gas supply unit configured to supply the pressurized gas to the first gas discharge device and the plurality of second gas discharge devices, and a controller configured to control the first gas discharge device, the plurality of second gas discharge devices, and the gas supply unit. The controller controls vertical movement of the first gas discharge device and the plurality of second gas discharge devices with respect to the upper bonding chuck, and a flow rate and pressure of the pressurized gas in the first gas discharge device and the plurality of second gas discharge devices, and the plurality of second gas discharge devices are apart from the first gas discharge device by an equal distance in a horizontal direction, and the plurality of second gas discharge devices are apart from one another at uniform intervals.

According to another aspect of the inventive concept, there is provided a substrate bonding apparatus for bonding a first substrate to a second substrate, including a lower bonding chuck configured to support the first substrate, an upper bonding chuck facing the lower bonding chuck and configured to support the second substrate, a gas discharge device including a pin actuator and a gas discharge pin provided through the center of the upper bonding chuck and configured to discharge pressurized gas to a top surface of the second substrate, a pressure sensor adjacent to the gas discharge device and embedded in a bottom surface of the upper bonding chuck, a distance sensor adjacent to the gas discharge device and embedded in a bottom surface of the upper bonding chuck, a gas supply unit including a gas storage tank, a gas pressurizing unit, and a gas supply valve and configured to supply pressurized gas to the gas discharge device, and a controller configured to control the gas discharge device and the gas supply unit. A vacuum groove for attaching the second substrate to the outside of a bottom surface of the upper bonding chuck is provided, and the gas discharge device comprises a gas discharge port for discharging the pressurized gas toward a top surface of the second substrate, the pressurized gas comprises gas or air including one or more of nitrogen, argon, neon, and helium, the controller controls vertical movement of the gas discharge device with respect to the upper bonding chuck, and a flow rate and pressure of the pressurized gas in the gas discharge device, the controller controls the gas discharge device to move downward following deformation of the center of the second substrate such that the gas discharge port does not contact a top surface of the first substrate as the center of the second substrate is deformed downward by the pressurized gas, the pressure sensor measures gas pressure of a cavity that is a space between the second substrate and a bottom surface of the upper bonding chuck, which is generated when the gas discharge device discharges the pressurized gas, the pin actuator is configured to move the gas discharge device up and down, and the gas discharge device protrudes from a bottom surface of the upper bonding chuck in a range of 0 μm to 300 μm to move up and down, the gas discharge port is spaced at least 50 μm vertically upward from the top surface of the second substrate, and the distance sensor measures a vertical distance between the center of the second substrate and a bottom surface of the upper bonding chuck.

### BRIEF DESCRIPTION OF THE DRAWINGS

Embodiments will be more clearly understood from the following detailed description taken in conjunction with the accompanying drawings in which:

FIG. 1 is a cross-sectional view illustrating a substrate bonding apparatus according to an embodiment;

FIG. 2 is a flowchart illustrating a substrate bonding method according to embodiments;

FIGS. 3A to 3D are cross-sectional views sequentially illustrating a substrate bonding method according to embodiments;

FIG. 4 is a cross-sectional view illustrating a substrate bonding apparatus according to an embodiment;

FIG. 5 is a cross-sectional view illustrating a substrate bonding apparatus according to an embodiment; and

FIGS. 6A and 6B are cross-sectional views illustrating a substrate bonding apparatus according to an embodiment.

### DETAILED DESCRIPTION OF THE EMBODIMENTS

Hereinafter, embodiments of the inventive concept will be described in detail with reference to the accompanying drawings.

Embodiments of the inventive concepts are provided and may be modified into various other forms, and the scope of the inventive concepts are not limited to the following embodiments. Rather, these embodiments are provided as examples within the present disclosure. In addition, in the drawings, a thickness or size of each layer is exaggerated for convenience and clarity of explanation.

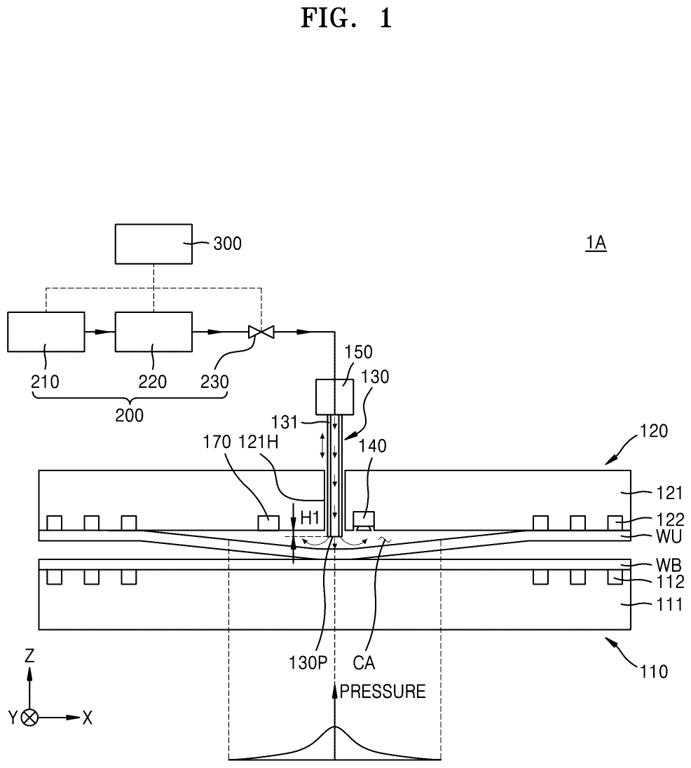

FIG. 1 is a cross-sectional view illustrating a substrate bonding apparatus 1A according to an embodiment.

Referring to FIG. 1, the substrate bonding apparatus 1A may include a lower bonding chuck 110, an upper bonding chuck 120, a gas discharge device 130, a gas supply unit 200, and a controller 300. The lower bonding chuck 110 may support a first substrate WB. In embodiments, the first substrate WB may include a single crystal substrate. In embodiments, the first substrate WB may include a silicon wafer. Single crystal silicon wafers may include p-type (e.g. boron doped), n-type (e.g. phosphorous doped) or even undoped. Alternatively, the wafers can be formed of a semiconductor material such as silicon carbide (SiC), germanium, gallium arsenide (GaAs), indium phosphide (InP), silicon-on-insulator (SOI), gallium nitride (GaN) etc. Or the wafer can be formed of a ceramic material such as zirconia (ZrO2) or alumina (Al2O3) etc.), or quartz, glass, fused silica, sapphire, metal, polymer, or other material. Wafer diameters can be e.g. from 100 mm or 150 mm to 200 mm or 300 mm, or in some cases even from 300 mm to 400 mm or even 450 mm.

The lower bonding chuck 110 may be configured to fix the first substrate WB to the lower bonding chuck 110 by, for example, vacuum pressure or electrostatic force. When the lower bonding chuck 110 is configured to fix the first substrate WB by vacuum pressure, the lower bonding chuck 110 may be configured to apply pressure lower than ambient pressure to a first surface of the first substrate WB facing a surface of a lower base 111. Alternatively, when the lower bonding chuck 110 is configured to fix the first substrate WB by electrostatic force, the lower bonding chuck 110 may include an electrode receiving power to generate electrostatic force for fixing the first substrate WB.

In embodiments, the lower bonding chuck 110 may include the lower base 111 on which the first substrate WB is disposed and a first vacuum groove 112 provided in the lower base 111. A first vacuum pump may apply vacuum pressure to the first vacuum groove 112 such that the first substrate WB is vacuum-held on a surface of the lower base 111, or may release vacuum pressure of the first vacuum groove 112 such that the vacuum applied to the first substrate WB is released. The first vacuum groove 112 may be formed in a portion in which at least the outer region of the first substrate comes into contact with the bonding chuck such that the outer region of the first substrate WB is fixed to the lower bonding chuck 110. However, the inventive concept is not limited thereto, and the lower base 111 may include a plurality of vacuum grooves arranged between the center and outer circumference of the lower base 111. For example, the plurality of vacuum grooves arranged in concentric circles may be formed in the lower base 111, and the first vacuum pump may be configured to control the vacuum pressure to the plurality of vacuum grooves formed in the lower base 111. Illustration of the first vacuum pump is omitted. Whether a single or plurality of vacuum grooves are provided, they can be positioned in a direction radially outward from the center of the first substrate, such as greater than 50% of the radius of the first substrate away from the center, such as greater than 75%.

The upper bonding chuck 120 may be arranged to face the lower bonding chuck 110. The upper bonding chuck 120 may support a second substrate WU such that a second bonding surface of the second substrate WU faces a first bonding surface of the first substrate WB.

The upper bonding chuck 120 may be configured to fix the second substrate WU by, for example, vacuum pressure or electrostatic force. When the upper bonding chuck 120 is configured to fix the second substrate WU by vacuum pressure, the upper bonding chuck 120 may be configured to apply pressure lower than ambient pressure to a first surface of the second substrate WU facing a surface of an upper base 121. Alternatively, when the upper bonding chuck 120 is configured to fix the second substrate WU by electrostatic force, the upper bonding chuck 120 may include an electrode receiving power to generate electrostatic force for fixing the second substrate WU.

In embodiments, the upper bonding chuck 120 may include the upper base 121 on which the second substrate WU is disposed and a second vacuum groove 122 provided in the upper base 121. A second vacuum pump may apply vacuum pressure to the second vacuum groove 122 such that the second substrate WU is vacuum-held on one surface of the upper base 121, or may release vacuum pressure of the second vacuum groove 122 such that the vacuum hold of the second substrate WU is released. Illustration of the second vacuum pump is omitted.

In embodiments, the upper bonding chuck 120 may include a gas discharge device 130 for applying pressure to the second substrate WU. The gas discharge device 130 may include a gas discharge pin 131 configured to reciprocate in a direction substantially perpendicular to the second substrate WU (for example, a Z direction) and a pin actuator 150 for driving the gas discharge pin 131. For example, the pin actuator 150 may include a multilayer piezoelectric actuator, a voice coil motor, and a rack and pinion combined with the voice coil motor.

The gas discharge pin 131 may be driven by the pin actuator 150 to descend toward the center of the second substrate WU. The gas discharge pin 131 may be provided in a pin hole 121H formed through the center of the upper base 121. While bonding between the first substrate WB and the second substrate WU is performed, the gas discharge pin 131 may change displacement of the center of the second substrate WU. The gas discharge pin 131 directs gas toward the center of the second substrate WU so that the vertical position of the center of the second substrate WU and the periphery of the center of the second substrate WU changes and the bottom surface of the second substrate WU may contact the top surface of the first substrate WB.

The gas discharge pin 131 may be connected to the gas supply unit 200. The gas supply unit 200 may include a gas storage tank 210, a gas pressurizing unit 220, and a gas supply valve 230.

The gas storage tank 210 may store gas or air including one or more of nitrogen, argon, neon, and helium. The gas may have significantly low reactivity with the first substrate WB and the second substrate WU. Therefore, the pressurized gas discharged through the gas discharge pin 131 may be a gas or air, including an inert gas such as a noble gas (argon, neon, helium etc.) or nitrogen, or a mixture of one or more of these gases.

The gas pressurizing unit 220 may be, for example, a compressor, and may pressurize the gas supplied from the gas storage tank 210 and may supply the pressurized gas to the gas discharge pin 131. The gas supply valve 230 may be opened or closed to control the flow rate of the pressurized gas applied to the top surface of the second substrate WU. Together with the gas supply valve 230 and the gas pressurizing unit 220, the pressure and flow rate of the pressurized gas applied to the second substrate WU may be controlled.

The gas discharge pin 131 may be moved upward or downward by the pin actuator 150. When the gas discharge pin 131 is not in operation, a gas discharge port 130P, which is the end surface of the gas discharge pin 131, may be at a vertical level equal to or higher than a vertical level of the bottom surface of the upper base 121. The gas discharge port 130P is the lower end of the gas discharge pin 131 and a hole through which the pressurized gas is discharged from the gas discharge pin 131.

As the pressurized gas reaches the top surface of the second substrate WU through the gas discharge port 130P, the gas discharge pin 131 may be moved downward by the pin actuator 150. The gas discharge pin 131 may move downward as bonding of the second substrate WU to the first substrate WB is performed. When the center of the second substrate WU is sufficiently pushed downward by the pressurized gas discharged from the gas discharge pin 131 so that the second substrate WU is bonded with sufficient force applied to the first substrate WB, the gas discharge pin 131 may be stopped.

The flow rate and pressure of the pressurized gas discharged through the gas discharge port 130P of the gas discharge pin 131 may be controlled by the gas supply unit 200. In addition, the degree of deformation caused by the pressurized gas on the second substrate WU may be controlled through a distance by which the gas discharge port 130P is apart from the top surface of the second substrate WU. For example, the flow rate and pressure of the gas supplied by the gas supply unit 200 can be held at substantially the same values during bonding, but the closer the gas discharge port 130P is to the top surface of the second substrate WU, the greater force received by the center of the second substrate WU with respect to which the gas discharge port 130P is positioned vertically downward. Alternatively, the flow of the gas (measured in liters per minute or cubic feet per minute) and/or the velocity of the gas (feet per second or meters per second) can be varied instead, or in addition to, the movement of the gas discharge port so as to alter the gas pressure applied to the wafer (pounds per square inch or Newtons per square meter).

A first height H1 at which the gas discharge port 130P of the gas discharge pin 131 protrudes from the bottom surface of the upper bonding chuck 120 may be, for example, 0 μm to 200 μm. For example, based on when the second substrate WU is not deformed, a range of displacement in which the center of the second substrate WU is deformed and protrudes downward is for example, greater than 0 μm to 200 μm, and the first height H1 may be 0 μm to 180 μm. That is, the gas discharge port 130P may be apart at least 50 μm vertically upward from the top surface of the second substrate WU. This is to induce slight deformation of the second substrate WU without the gas discharge port 130P contacting the top surface of the second substrate WU. The first height H1 may be in a range smaller than the range of the displacement in which the center of the second substrate WU is deformed and protrudes downward.

Pressure applied to the center of the second substrate WU by the pressurized gas discharged from the gas discharge port 130P of the gas discharge pin 131 may be, for example, greater than 0 Pa to 100 Pa. For example, the pressure applied to the center of the second substrate WU by the pressurized gas discharged from the gas discharge port 130P may be, for example, greater than 0 Pa to 40 Pa. The pressure applied to the second substrate WU by the pressurized gas discharged according to the horizontal cross-sectional area of the gas discharge port 130P, the distance between the gas discharge port 130P and the second substrate WU, and the shape of the gas discharge port 130P may vary.

The upper bonding chuck 120 may include a distance sensor 140 and a pressure sensor 170 on the bottom surface of the upper bonding chuck 120. The distance sensor 140 and the pressure sensor 170 may be provided in a groove recessed by a predetermined depth from the bottom surface of the upper bonding chuck 120.

The distance sensor 140 may be provided adjacent to the pin hole 121H. Accordingly, the distance sensor 140 may measure the distance by which the center of the second substrate WU is apart from the bottom surface of the upper base 121. The distance sensor 140 may continuously measure the distance by which the second substrate WU is apart from the upper base 121 and may transmit the result to the controller 300. The controller 300 controls the pin actuator 150 to prevent the gas discharge port 130P of the gas discharge pin 131 from contacting the top surface of the second substrate WU.

The pressure sensor 170 may be apart from the pin hole 121H by a predetermined distance and may be recessed in the bottom surface of the upper base 121. The pressure sensor 170 may measure pressure of a cavity CA generated between the upper base 121 and the second substrate WU due to deformation of the second substrate WU. The pressure sensor 170 may continuously measure pressure and may transmit the result to the controller 300.

When the pressure of the cavity CA is excessive, the second substrate WU attached to the upper base 121 may be detached from the upper base 121 and separate from the second vacuum groove 122. The controller 300 may control the pressure and flow rate of the pressurized gas supplied through the gas discharge pin 131 such that the downward force received by the second substrate WU is not greater by the pressure of the pressurized gas supplied to the cavity CA than by the force to which the second substrate WU is attached to the upper base 121 by the second vacuum groove 122.

The controller 300 may control the overall operation of the substrate bonding apparatus 1A. For example, the pressure and flow rate of the pressurized gas supplied through the gas discharge device 130 may be controlled, and the position and movement of the gas discharge pin 131 may be controlled.

The controller 300 may be implemented as hardware, firmware, software, or any combination thereof. For example, the controller 300 may be a computing device such as a workstation computer, a desktop computer, a laptop computer, or a tablet computer. The controller 300 may be a simple controller 300, a complex processor such as a microprocessor, a central processing unit (CPU), or a graphics processing unit (GPU), a processor configured by software, dedicated hardware, or firmware. The controller 300 may be implemented by, for example, a general-purpose computer or application-specific hardware such as a digital signal processor (DSP), a field programmable gate array (FPGA), or an application specific integrated circuit (ASIC).

In a typical substrate bonding apparatus, a pressing pin contacts the center of an upper substrate to apply downward force to the center of the upper substrate, thereby bonding a lower substrate to the upper substrate. In the typical substrate bonding apparatus using such a direct pressing method, when the pressurizing pin applies force to the upper substrate, deformation occurs at a point at which force is received by the pressurizing pin and around the point at which force is received. When deformation occurs in the upper substrate due to direct pressing, the possibility of misalignment between the upper substrate and the lower substrate increases in the deformed portion of the upper substrate. Therefore, the typical substrate bonding apparatus using the direct pressurizing method may have a relatively low yield in wafer-to-wafer bonding.

The substrate bonding apparatus 1A according to an embodiment presses the top surface of the second substrate WU, but the second substrate WU receives a force through the pressurized gas discharged from the gas discharge pin 131 rather than being directly presses by a pressurizing pin. The pressurized gas is not only subjected to a downward force at the center of the second substrate WU positioned vertically below the gas discharge port 130P of the gas discharge pin 131 but also at locations deviating from the center of the second substrate WU. That is, through dispersion of naturally occurring gas flow rate, the pressurized gas discharged by the gas discharge device 130 is dispersed and the greatest force may be applied to the center of the second substrate WU while simultaneously applying force in a radial direction away from the center of the second substrate WU. A graph of the pressure applied by the pressurizing gas to the second substrate WU is illustrated as an example in FIG. 1. As can be seen in the graph of FIG. 1 a pressure gradient extends from a peak pressure in the center of the wafer proximate the gas discharge port 130p and decreases in a radial direction towards edge of the wafer.

Because pressure having a distribution of which the magnitude decreases as the distance from the center of the second substrate WU increases may be applied through the pressurized gas, excessive local deformation of the second substrate WU may be reduced or prevented. By reducing or preventing excessive local deformation of the second substrate WU, misalignment of wafer-to-wafer bonding may be reduced. Therefore, the substrate bonding apparatus 1A according to an embodiment may improve productivity and yield of wafer-to-wafer bonding.

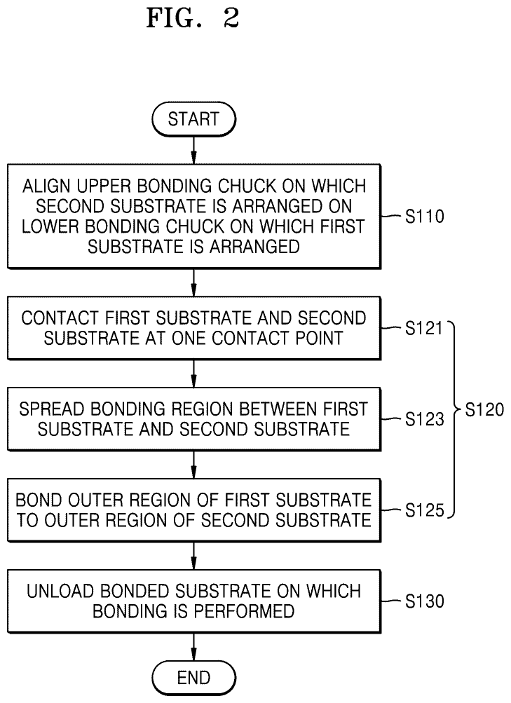

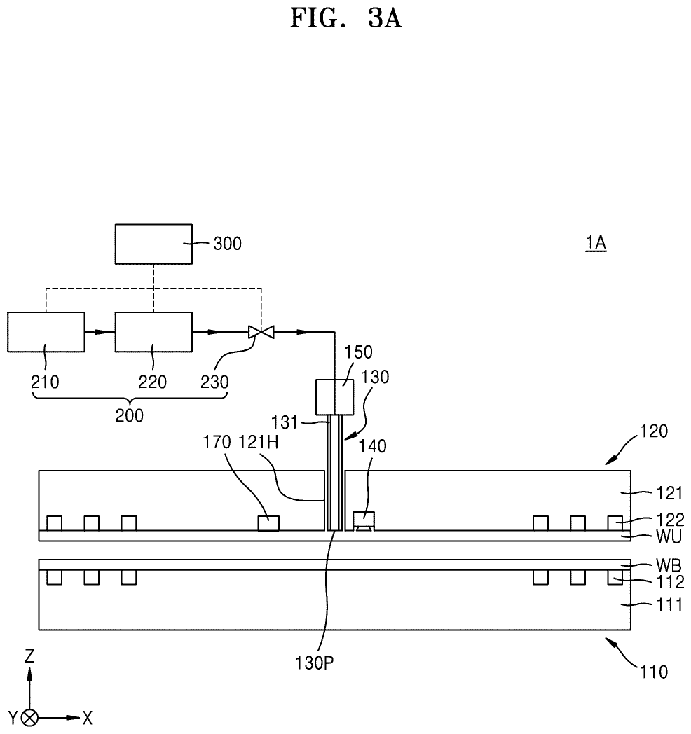

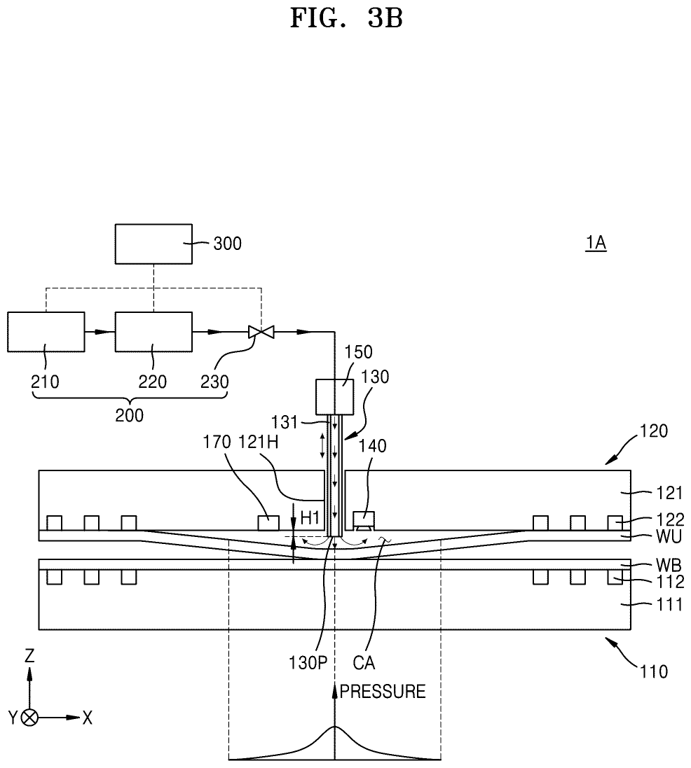

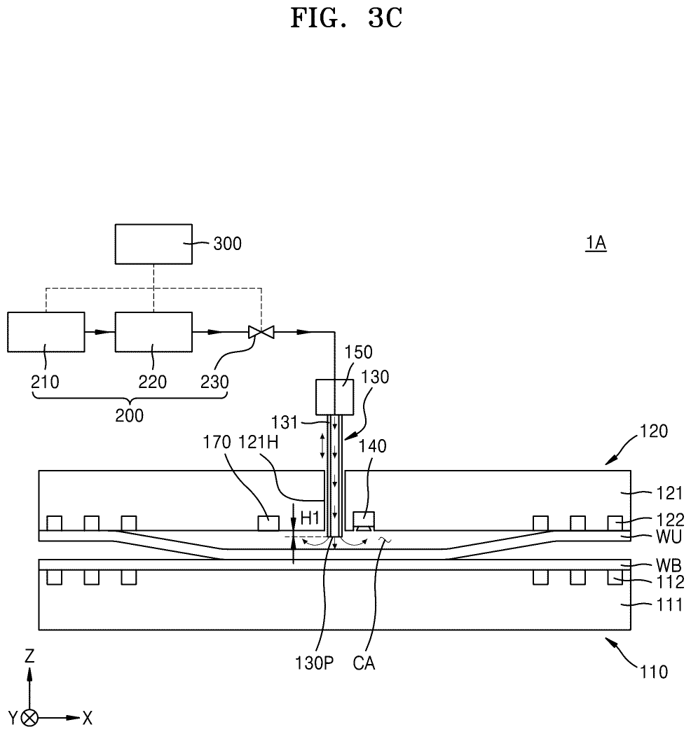

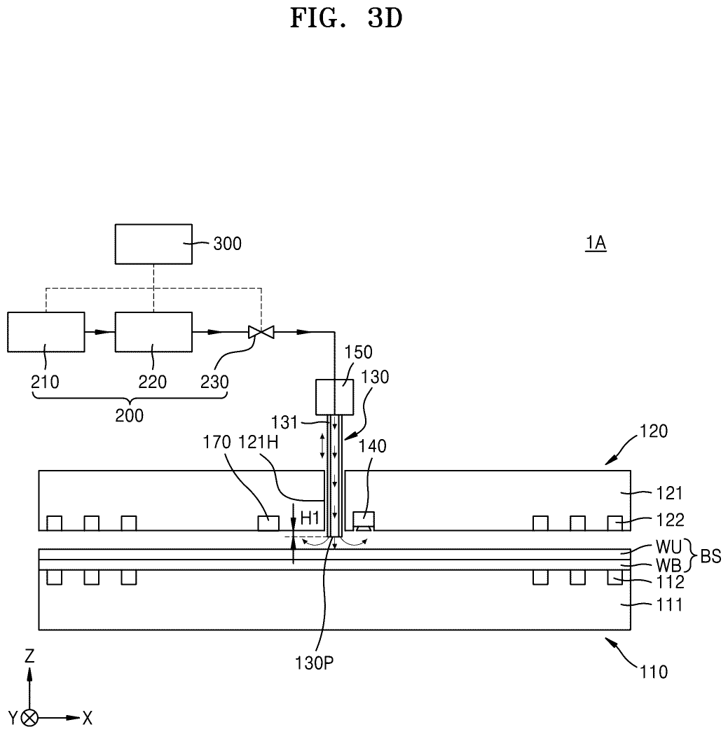

FIG. 2 is a flowchart illustrating a substrate bonding method according to embodiments. FIGS. 3A to 3D are cross-sectional views sequentially illustrating a substrate bonding method according to embodiments. Hereinafter, the substrate bonding method using the substrate bonding apparatus according to embodiments is described in detail with reference to FIGS. 2 and 3A to 3D.

Referring to FIGS. 2 and 3A, the upper bonding chuck 120 on which the second substrate WU is arranged is aligned with the lower bonding chuck 110 on which the first substrate WB is arranged in operation S110.

In operation S110, the first substrate WB may be mounted on the lower bonding chuck 110 such that an inactive surface of the first substrate WB contacts the lower bonding chuck 110, and the second substrate WU may be mounted on the upper bonding chuck 120 such that an inactive surface of the second substrate WU contacts the upper bonding chuck 120. For example, the lower bonding chuck 110 may vacuum-attach the first substrate WB such that the first substrate WB is fixed, and the upper bonding chuck 120 may vacuum-adsorb the second substrate WU such that the second substrate WU is fixed. The second bonding surface of the second substrate WU mounted on the upper bonding chuck 120 may face a first bonding surface of the first substrate WB mounted on the lower bonding chuck 110.

In operation S110, the lower bonding chuck 110 may be aligned with the upper bonding chuck 120 in a vertical direction (for example, the Z direction). For the alignment of the lower bonding chuck 110 with the upper bonding chuck 120, at least one of the lower bonding chuck 110 and the upper bonding chuck 120 may move in a horizontal direction (for example, an X direction and/or a Y direction) and may also rotate in the vertical direction (for example, the Z direction).

In operation S110, the upper bonding chuck 120 may descend toward the lower bonding chuck 110 to separate the first bonding surface of the first substrate WB from the second bonding surface of the second substrate WU by a predetermined appropriate distance. For example, the distance between the first bonding surface of the first substrate WB and the second bonding surface of the second substrate WU may be about 50 μm to about 300 μm. In embodiments, the distance between the first bonding surface of the first substrate WB and the second bonding surface of the second substrate WU may be about 200 μm. Alternatively, in order to control the distance between the first substrate WB and the second substrate WU, the lower bonding chuck 110 may be raised, the upper bonding chuck 120 may be lowered, or the lower bonding chuck 110 may be raised and the upper bonding chuck 120 may be lowered simultaneously.

In the current specification, a case in which thicknesses of the first substrate WB and the second substrate WU in the vertical direction are each 50 μm and the distance between the first bonding surface of the first substrate WB and the second bonding surface of the second substrate WU is about 200 μm is described as an example. However, the inventive concept is not limited thereto.

Referring to FIG. 2, after the lower bonding chuck 110 is aligned with the upper bonding chuck 120, bonding between the first substrate WB and the second substrate WU is performed in operation S120. In embodiments, the bonding between the first substrate WB and the second substrate WU may include contacting the first substrate WB and the second substrate WU at a contact point in operation S121, spreading a bonding region between the first substrate WB and the second substrate WU in operation S123, and bonding the outer region of the first substrate WB and the outer region of the second substrate WU in operation S125.

Referring to FIGS. 2 and 3B, in order to initiate the bonding between the first substrate WB and the second substrate WU in operation S121, the pressurized gas discharged from the gas discharge pin 131 presses the second substrate WU towards the first substrate WB to contact the second substrate WU at one contact point. As the pressurized gas by the gas discharge pin 131 applies pressure to the center of the second substrate WU, the second substrate WU pressed by the gas discharge pin 131 convexly deforms downward such that the first substrate WB and the second substrate WU may contact each other at one contact point. The contact point may be defined as a bonding initiation point at which the bonding between the first substrate WB and the second substrate WU begins. For example, the center of the first bonding surface of the first substrate WB meets the center of the second bonding surface of the second substrate WU at the bonding initiation point. In FIG. 3B, the first bonding surface of the first substrate WB may be the top surface of the first substrate WB, and the second bonding surface of the second substrate WU may be the bottom surface of the second substrate WU.

Referring to FIGS. 2 and 3C, in operation S123, the bonding region between the first substrate WB and the second substrate WU may gradually spreads from the bonding initiation point toward the outer regions of the first substrate WB and the second substrate WU. The bonding region between the first substrate WB and the second substrate WU may refer to a portion in which the first bonding surface of the first substrate WB and the second bonding surface of the second substrate WU bond to each other.

In embodiments, the spread of the bonding region between the first substrate WB and the second substrate WU may occur spontaneously without applying additional external force. For example, the first bonding surface of the first substrate WB and the second bonding surface of the second substrate WU may each be a plasma-treated or wet-treated surface. In one example, an —OH functional group is attached to each of the first bonding surface of the first substrate WB and the second bonding surface of the second substrate WU such that, when bonding the first substrate WB to the second substrate WU, the —OH functional group of the first bonding surface of the first substrate WB and the —OH functional group of the second bonding surface of the second substrate WU may be spontaneously bonded through a hydrogen bond. In an example, the first bonding surface of the first substrate WB and the second bonding surface of the second substrate WU undergo preprocessing to remove impurities, such as by using dry cleaning (e.g. a UV/ozone cleaning or plasma treatment) or a wet chemical cleaning (e.g. a solution having deionized water, hydrogen peroxide and an acid or base). The pretreatment results in-OH functional groups attached to silicon (Si—OH) on each wafer such that when they are brought into contact with each other bonding takes place forming —Si—O—Si— between the wafers and bonding the wafers together. This initial bond is followed by annealing at a higher temperature to increase the —Si—O—Si— bonds between the wafers. Other suitable bonding methods can also be used.

Alternatively, because the upper bonding chuck 120 vacuum-holds the outer region of the second substrate WU in operation S123, the bonding region between the first substrate WB and the second substrate WU does not spread to the outer regions of the first substrate WB and the second substrate WU and may spread only to a point at which attractive force between surfaces of the first substrate WB and the second substrate WU and elastic restoring force of the second substrate WU are balanced.

Referring to FIGS. 2 and 3D, when the upper bonding chuck 120 releases the vacuum pressure applied to the outer region of the second substrate WU in operation S125, the outer region of the second substrate WU may freely fall toward the outer region of the first substrate WB, and the outer region of the second substrate WU and the outer region of the first substrate WB may be bonded to each other. When the bonding between the outer region of the first substrate WB and the outer region of the second substrate WU is completed, a bonded substrate BS, in which the first bonding surface of the first substrate WB and the second bonding surface of the second substrate WU are entirely bonded, may be formed.

Referring to FIG. 2, when the bonding between the first substrate WB and the second substrate WU is completed, the bonded substrate BS is unloaded in operation S130. In order to unload the bonded substrate BS, the upper bonding chuck 120 may be moved in a direction away from the lower bonding chuck 110, and the lower bonding chuck 110 may entirely release the vacuum pressure to the bonded substrate BS.

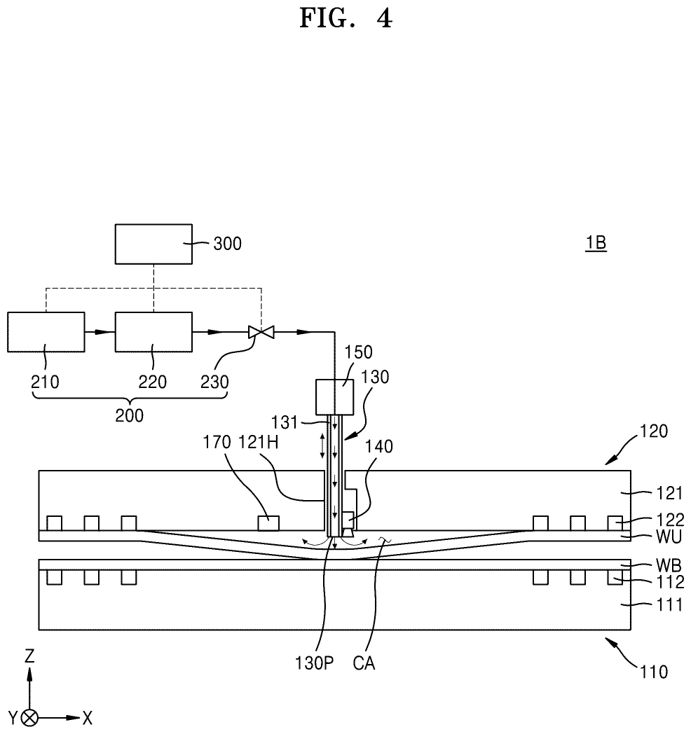

FIG. 4 is a cross-sectional view illustrating a substrate bonding apparatus 1B according to an embodiment. Redundant descriptions with those given above may be omitted.

Referring to FIG. 4, the substrate bonding apparatus 1B may include a lower bonding chuck 110, an upper bonding chuck 120, a gas discharge device 130, a gas supply unit 200, and a controller 300. In addition, the upper bonding chuck 120 may include a pressure sensor 170 on the bottom surface of the upper bonding chuck 120. The pressure sensor 170 may be provided in a groove recessed by a predetermined depth from the bottom surface of the upper bonding chuck 120. The gas discharge device 130 may include a gas discharge pin 131 configured to reciprocate in a direction substantially perpendicular to a second substrate WU (for example, the Z direction), a distance sensor 140A attached to a side of the lower end of the gas discharge pin 131, and a pin actuator 150 for driving the gas discharge pin 131.

The distance sensor 140A may be attached to the side of the lower end of the gas discharge pin 131 such that the distance sensor 140A may simultaneously perform a vertical reciprocating motion of the gas discharge pin 131 with the gas discharge pin 131. Accordingly, the distance sensor 140A may measure the distance by which the center of the second substrate WU is apart from the bottom surface of an upper base 121. The distance sensor 140A may continuously measure the distance between the gas discharge port 130P that is an end of the gas discharge pin 131 and the top surface of the second substrate WU and may transmit the measurement result to the controller 300. The controller 300 controls the pin actuator 150 to prevent a gas discharge port 130P of the gas discharge pin 131 from contacting the top surface of the second substrate WU.

At the same time, the pin actuator 150 may continuously measure a degree to which the gas discharge pin 131 protrudes from the upper base 121 through a degree to which the pin actuator 150 moves and may transmit the measurement result to the controller 300.

A recess in which the distance sensor 140A is to be provided on a side of a pin hole 121H formed in the upper base 121 may be formed from the bottom surface of the upper base 121 toward the inside of the upper base 121 such that the distance sensor 140A may be provided on the side of the lower end of the gas discharge pin 131.

In the substrate bonding apparatus 1B according to an embodiment, the gas discharge pin 131 may be prevented from contacting the top surface of the second substrate WU. Therefore, because misalignment of wafer-to-wafer bonding may be reduced, the substrate bonding apparatus 1B may improve productivity and yield of wafer-to-wafer bonding.

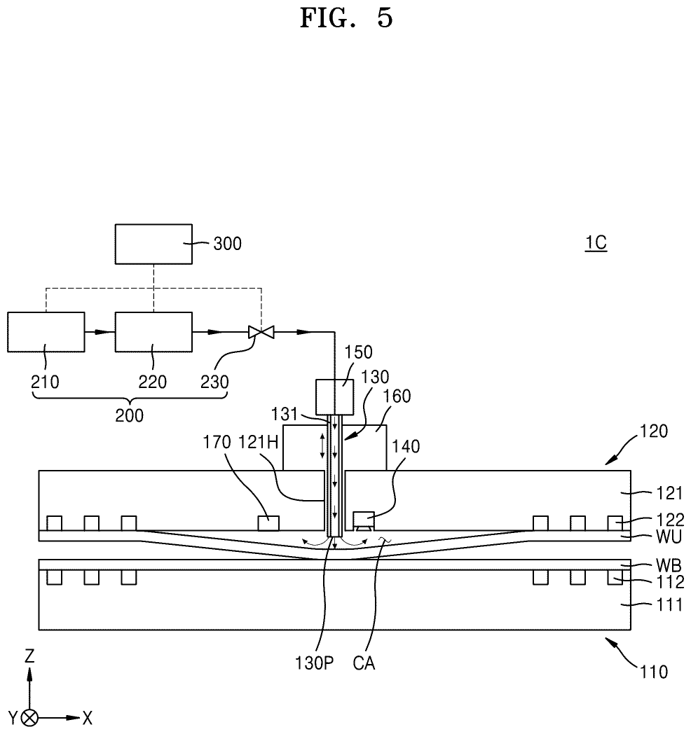

FIG. 5 is a cross-sectional view illustrating a substrate bonding apparatus 1C according to an embodiment. Redundant descriptions with those given above may be omitted.

Referring to FIG. 5, the substrate bonding apparatus 1C may include a lower bonding chuck 110, an upper bonding chuck 120, a gas discharge device 130, a gas supply unit 200, a controller 300, and a gas control device 160.

When pressurized gas is discharged from a gas discharge port 130P of a gas discharge pin 131 to a cavity CA, pressure in the cavity CA becomes excessive and a second substrate WU may be separated from the bottom surface of the upper bonding chuck 120. The gas pressure in the cavity CA may be greater than vacuum force of the second substrate WU by a second vacuum groove 122 provided in an upper base 121. In order to prevent the gas pressure in the cavity CA from being greater than the adsorption force of the second substrate WU, the controller 300 may continuously receive a pressure measurement value in the cavity CA from the pressure sensor 170 to control the flow rate and pressure of a gas supplied by the gas supply unit 200 according to the received pressure value.

The gas control device 160 may be provided on the top surface of the upper bonding chuck 120 to cover a gap between a pin hole 121H and the gas discharge pin 131. As in operation S121 described above, the pressurized gas discharged from the gas discharge pin 131 applies force to the second substrate WU to bring the first substrate WB and the second substrate WU into contact at one contact point. At this time, in particular, the gas discharged from the gas discharge pin 131 must apply greater pressure to the center of the second substrate WU than to a surrounding region of the center of the second substrate WU.

When the cavity CA is completely sealed and gas is continuously supplied through the gas discharge pin 131, the pressure of the entire cavity CA increases so that the second substrate WU may be separated from the upper base 121 at an unintended time. Instead of applying greater pressure to the center of the top surface of the second substrate WU than to the surrounding region, gas pressure may be applied overall to the top surface of the second substrate WU apart from the bottom surface of the upper base 121. Therefore, the cavity CA is not sealed, and the gas in the cavity CA escapes through the gap between the pin hole 121H and the gas discharge pin 131, but the gas discharged from the cavity CA may flow into the gas control device 160.

The gas control device 160 may discharge all of the pressurized gas flowing out of the cavity CA to the outside of the gas control device 160, may discharge only a part of the pressurized gas, or may not discharge the pressurized gas flowing out of the cavity CA. That is, when the gas pressure in the cavity CA is high, the gas control device 160 may control the flow rate of the gas flowing out of the gas control device 160 to discharge the gas. When the flow rate of the gas flowing out of the gas control device 160 is less than the flow rate of the pressurized gas flowing into the gas control device 160 from the cavity CA, internal pressure of the cavity CA may increase. Conversely, when the flow rate of the gas flowing out of the gas control device 160 is greater than the flow rate of the pressurized gas flowing into the gas control device 160 from the cavity CA, the internal pressure of the cavity CA may decrease.

The gas control device 160 may include a pipe through which gas escaping through the gap between the pin hole 121H and the gas discharge pin 131 flows, and a valve provided on the pipe. Based on the pressure value measured by the pressure sensor 170 described above, a valve of the gas control device 160 may be opened or closed so that the pressure in the cavity CA is not excessive to control the flow rate of the gas flowing out of the cavity CA. The gas flowing out of the cavity CA may be discharged to the outside through the gas control device 160, or may flow into a gas storage tank 210 through the gas control device 160 to be reused.

The gas control device 160 may include a gas tank and the valve on the pipe continuously connected to the gap between the pin hole 121H and the gas discharge pin 131. The gas control device 160 may be connected to the controller 300 to control the valve included in the gas control device 160 so that the pressure in the cavity CA is not excessive.

In the substrate bonding apparatus 1C according to an embodiment, the gas discharge pin 131 may be prevented from contacting the top surface of the second substrate WU, and the center of the second substrate WU may be pressed without the second substrate WU being separated from the upper base 121. Therefore, because the misalignment of wafer-to-wafer bonding may be reduced and a wafer-to-wafer bonding process may be performed smoothly, the substrate bonding apparatus 1C may improve the productivity and yield of wafer-to-wafer bonding.

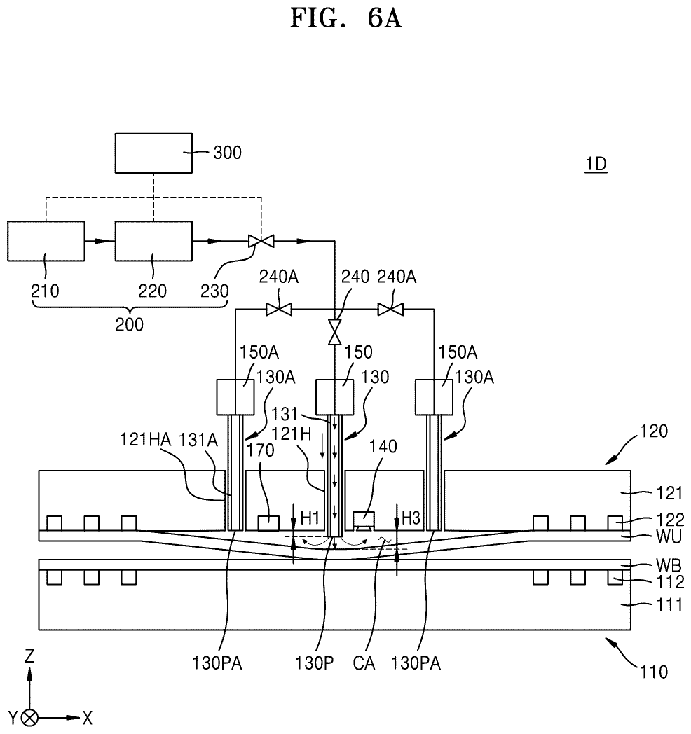

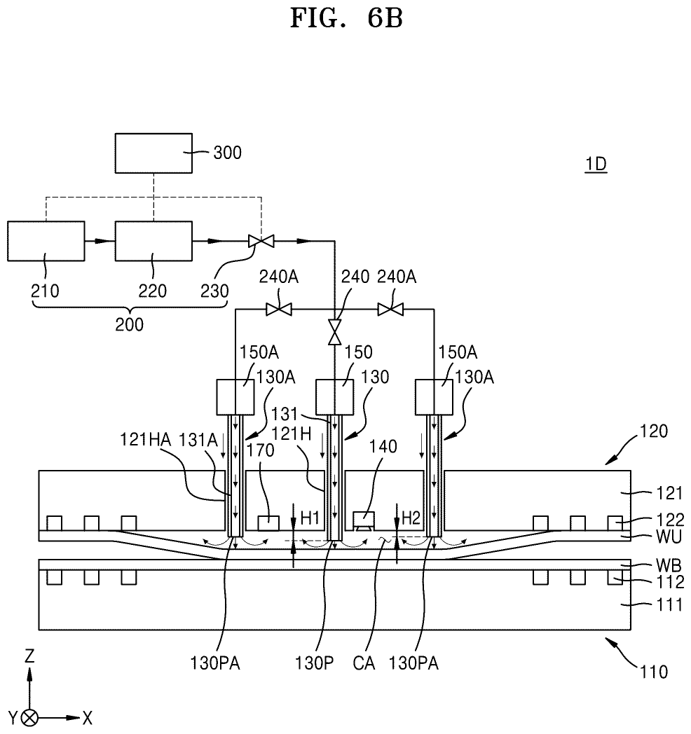

FIGS. 6A and 6B are cross-sectional views illustrating a substrate bonding apparatus 1D according to an embodiment. Redundant descriptions with those given above may be omitted.

Referring to FIGS. 6A and 6B, the substrate bonding apparatus 1D may include a lower bonding chuck 110, an upper bonding chuck 120, a first gas discharge device 130, a second gas discharge device 130A, a gas supply unit 200, and a controller 300.

In embodiments, the upper bonding chuck 120 may include the first gas discharge device 130 and one or more second gas discharge devices 130A for pressing a second substrate WU. The one or more second gas discharge devices 130A may each include a second gas discharge pin131A configured to reciprocate in a direction substantially perpendicular to the second substrate WU (for example, the Z direction) and a second pin actuator 150A for driving the second gas discharge pin 131A. In addition, a plurality of second gas discharge devices 130A may be provided.

The plurality of second gas discharge devices 130A may be disposed apart from other adjacent second gas discharge devices 130A at intervals, e.g. uniform intervals, with respect to the first gas discharge device 130. For example, when three second gas discharge devices 130A are provided, the three second gas discharge devices 130A may be apart from one another at 120° intervals with respect to the first gas discharge device 130. For example, when four second gas discharge devices 130A are provided, the four second gas discharge devices 130A may be positioned apart from one another at 90° intervals with respect to the first gas discharge device 130. A larger number of second gas discharge devices disposed at lower degree intervals (72°, 60°, 45°, etc.) can also be provided. In addition, third gas discharge devices disposed radially outward from (and operable together with or independently from) the second gas discharge devices can be provided also at intervals (e.g. 120°, 90°, 72°, 60°, 45°, etc.).

The first gas discharge pin 131 may be driven by the pin actuator 150 to move toward the center of the second substrate WU. The first gas discharge pin 131 may be provided in a first pin hole 121H formed through the center of an upper base 121. A second pin hole 121HA apart from the first pin hole 121H and vertically penetrating the upper base 121 may be provided in the upper base 121. The second gas discharge pin 131A may be arranged in the second pin hole 121HA.

A first height H1, at which the gas discharge port 130P of the first gas discharge pin 131 protrudes from the bottom surface of the upper bonding chuck 120, may be equal to or greater than a second height H2, at which a gas discharge port 130PA of the second gas discharge pin 131A protrudes from the bottom surface of the upper bonding chuck 120. Pressurized gas at the same pressure may be supplied to the first gas discharge device 130 and the second gas discharge device 130A. However, because the second height H2 is equal to or less than the first height H1, the pressure applied by the first gas discharge pin 131 to the second substrate WU may be less than the pressure applied by the second gas discharge pin 131A to the second substrate WU.

FIG. 6A may illustrate operation S121 of the first substrate WB contacting the second substrate WU at one contact point. In operation S121, in the substrate bonding apparatus 1D, the second gas discharge pin 131A may not apply gas to the second substrate WU and the first gas discharge pin 131 may apply gas to the second substrate WU. That is, in operation S121, because the first substrate WB and the second substrate WU must be brought into contact at one contact point, only the first gas discharge pin 131 above the center of the second substrate WU may discharge gas.

When the first substrate WB and the second substrate WU contact each other at one contact point, the second gas discharge device 130A may discharge pressurized gas. For example, when the pressurized gas is discharged from the first gas discharge device 130 and the first substrate WB contacts the second substrate WU at one contact point as illustrated in FIG. 6A, the second substrate WU and the upper bonding chuck 120 may be apart from each other below the plurality of second gas discharge devices 130A. A distance sensor 140 may measure the distance between the second substrate WU and the upper bonding chuck 120 when the first substrate WB contacts the second substrate WU at one contact point and may transmit the measured value to the controller 300. When it is determined that the measured value corresponds to the contact between the first substrate WB and the second substrate WU at one contact point, the controller 300 may control the plurality of second gas discharge devices 130A to start discharging the pressurized gas.

That is, when a third height H3 that is the distance between the second substrate WU and the upper bonding chuck 120 from the distance sensor 140 is the largest during a bonding process, the controller 300 may control the pressurized gas to be discharged from the plurality of second gas discharge devices 130A. When the third height H3 is the largest during the bonding process, the third height H3 means the distance between the second substrate WU and the upper bonding chuck 120 from the distance sensor 140 when the first substrate WB contacts the second substrate WU at one contact point.

A case in which thicknesses of a first substrate WB and the second substrate WU in the vertical direction are each 50 μm, and the distance between a first bonding surface of the first substrate WB and a second bonding surface of the second substrate WU is about 200 μm is described as an example. When the second substrate WU contacts the first substrate WB at one contact point, the distance between the second substrate WU and the upper bonding chuck 120 may be 200 μm. When the value measured by the distance sensor 140 after the pressurized gas is discharged from the first gas discharge device 130 is 200 μm, the controller 300 may determine that the first substrate WB contacts the second substrate WU at one contact point. Accordingly, the controller 300 may control the plurality of second gas discharge devices 130A to start discharging the pressurized gas.

FIG. 6B may illustrate operation S123 of spreading the bonding region between the first substrate WB and the second substrate WU. In operation S123, the first gas discharge pin 131 and the second gas discharge pin 131A may apply gas to the second substrate WU. However, depending on the pressure of the gas applied by the second gas discharge pin 131A, the speed at which the bonding region between the first substrate WB and the second substrate WU gradually spreads from a bonding start point toward the outer regions of the first substrate WB and the second substrate WU, may vary. In order to prevent the bonding region between the first substrate WB and the second substrate WU from spreading excessively and rapidly, pressure applied by the second gas discharge pin 131A to the second substrate WU may be less than pressure applied by the first gas discharge pin 131 to the second substrate WU.

That is, the length of the first gas discharge pin 131 protruding from the bottom surface of the upper base 121 may be less than the length of the second gas discharge pin 131A protruding from the bottom surface of the upper base 121. Alternatively, the flow rate and pressure of the gas supplied by the second gas discharge pin 131A may be less than the flow rate and pressure of the gas supplied by the first gas discharge pin 131.

The controller 300 may control the flow rate and pressure of the gas supplied to the first gas discharge pin 131 and the second gas discharge pin 131A. That is, valves for controlling the supply of gas to the first gas discharge pin 131 and the second gas discharge pin 131A may be provided, respectively. That is, a first gas valve 240 and a second gas valve 240A may be provided on pipes through which the gas passes through the gas supply valve 230 and is supplied to the first gas discharge pin 131 and the second gas discharge pin 131A, respectively. The first gas valve 240 may control the flow rate of gas supplied to the first gas discharge pin 131, and the second gas valve 240A may control the flow rate of gas supplied to the second gas discharge pin 131A. Alternatively, the first gas valve 240 may open or close the pipe connected to the first gas discharge pin 131 to control the supply of gas, and the second gas valve 240A may open or close the pipe connected to the second gas discharge pin 131A to control the supply of gas.

The substrate bonding apparatus 1D according to an embodiment may include a plurality of pressurizing pins. Accordingly, excessive deformation of the second substrate WU may be reduced or prevented during wafer-to-wafer bonding, and the speed at which the bonding region between the first substrate WB and the second substrate WU gradually spreads outward may be controlled. Therefore, the substrate bonding apparatus 1D may improve productivity and yield of wafer-to-wafer bonding.

In the examples above the areas providing positive pressure include a central gas discharge device 130 with movable pin 130 and second gas discharge devices 130A with movable pins 131A arranged equidistant from the central pin 130 and from each other. However other arrangements that are not equidistant, or without movable pins (e.g., changes in gas volume or velocity used to control pressure on the wafer) can be used. Also the negative pressure areas (vacuum grooves 122) can be concentric rings or a series of openings similar to the series of opening disclosed above with respect to the gas discharge devices 130A. In some examples, the concentric rings or openings for positive or negative pressure can be switched between negative and positive pressure and which can be operated at different times depending upon their radial location and the point of time within the bonding process. Additionally, though the gas discharge devices and pins are illustrated as being part of the upper bonding chuck, they can alternatively (or in addition) be provided in the bottom chuck. And, though the chucks are illustrated as being disposed one above the other, they can also be disposed horizontally from each other with the wafers to be bonded being positioned vertically, or other arrangement other than that illustrated in the figures.

While the inventive concept has been particularly shown and described with reference to embodiments thereof, it will be understood that various changes in form and details may be made therein without departing from the spirit and scope of the following claims.

What is claimed is:

1. A substrate bonding apparatus for bonding a first substrate to a second substrate, the substrate bonding apparatus comprising:
a first bonding chuck configured to support the first substrate;
a second bonding chuck facing the first bonding chuck and configured to support the second substrate;
a gas discharge device provided through a first location of the second bonding chuck and configured to discharge a pressurized gas to an outer surface of the second substrate, which is a surface disposed on an opposite side of the second substrate to a surface to be bonded;
a gas supply unit configured to supply the pressurized gas to the gas discharge device; and
a controller configured to control the gas discharge device and the gas supply unit, wherein the controller controls movement of the gas discharge device with respect to the second bonding chuck.

2. The substrate bonding apparatus of claim 1, wherein the gas discharge device comprises a gas discharge port discharging the pressurized gas toward the outer surface of the second substrate, and
wherein the controller controls the gas discharge device to move towards the second substrate causing deformation of the first location of the second substrate and controlling such that the gas discharge port does not contact the outer surface of the second substrate as the first location of the second substrate is deformed towards the first substrate by the pressurized gas.

3. The substrate bonding apparatus of claim 1, wherein the gas supply unit comprises a gas storage tank, a gas pressurizing unit, and a gas supply valve, and
wherein the storage tank has therein a pressurized gas comprises air or a gas selected from one or more of nitrogen, argon, neon, and helium.

4. The substrate bonding apparatus of claim 2, further comprising a pressure sensor adjacent to the gas discharge device and disposed in the second bonding chuck, wherein the pressure sensor measures gas pressure of a cavity that is a space between the second substrate and a surface of the second bonding chuck, which is generated when the gas discharge device discharges the pressurized gas.

5. The substrate bonding apparatus of claim 2, wherein pressure of the pressurized gas discharged from the gas discharge port is greater than 0 Pa to 40 Pa.

6. The substrate bonding apparatus of claim 2, further comprising a pin actuator, wherein the pin actuator is configured to move the gas discharge device relative to the second substrate, and the gas discharge device protrudes from a surface of the second bonding chuck in a range of 0 μm to 300 μm, and
wherein the gas discharge port is spaced by at least 20 μm from the outer surface of the second substrate.

7. The substrate bonding apparatus of claim 2, further comprising a distance sensor adjacent to the gas discharge device and disposed in the second bonding chuck, wherein the distance sensor measures a distance between the first location of the second substrate and a surface of the second bonding chuck.

8. The substrate bonding apparatus of claim 2, further comprising a distance sensor attached to a side of the gas discharge device, wherein the distance sensor is provided at a position equal to or greater than the distance between the gas discharge port and the second substrate and measures a distance between the first location of the second substrate and the outer surface of the second bonding chuck.

9. The substrate bonding apparatus of claim 2, wherein the second bonding chuck further comprises a vacuum groove, and
wherein the vacuum groove is arranged on the second bonding chuck, and the vacuum groove fixes the second substrate to the second bonding chuck.

10. The substrate bonding apparatus of claim 4, further comprising a gas control device covering a gap between the gas discharge device and the second bonding chuck and including a valve on the second bonding chuck, wherein the pressurized gas flows into the gas control device from the cavity and the gas control device controls an amount of gas flowing out of the gas control device from the cavity to control internal pressure of the cavity.

11. A substrate bonding apparatus for bonding a first substrate to a second substrate, the substrate bonding apparatus comprising:
a first bonding chuck configured to support the first substrate;
a second bonding chuck facing the first bonding chuck and configured to support the second substrate;
a first gas discharge device provided through the first location of the second bonding chuck and configured to discharge a pressurized gas to an outer surface of the second substrate;
a plurality of second gas discharge devices penetrating the second bonding chuck, apart from the first gas discharge device, and configured to discharge the pressurized gas to an outer surface of the second substrate;
a gas supply unit configured to supply the pressurized gas to the first gas discharge device and the plurality of second gas discharge devices; and
a controller configured to control the first gas discharge device, the plurality of second gas discharge devices, and the gas supply unit, wherein the controller controls movement of the first gas discharge device and the plurality of second gas discharge devices with respect to the second bonding chuck, and
wherein the plurality of second gas discharge devices are disposed apart from the first gas discharge device in a direction orthogonal to the direction of the movement of the second gas discharge devices, and the plurality of second gas discharge devices are apart from one another at particular intervals.

12. The substrate bonding apparatus of claim 11, wherein the first gas discharge device comprises a first gas discharge port configured to discharge the pressurized gas toward an outer surface of the second substrate, and each of the plurality of second gas discharge devices comprises a second gas discharge port configured to discharge the pressurized gas toward an outer surface of the second substrate, and
wherein the controller controls the first gas discharge device and the plurality of second gas discharge devices to move toward the second substrate causing deformation of the first location of the second substrate but where the first gas discharge port and the second gas discharge port do not contact the outer surface of the second substrate as the first location of the second substrate is deformed towards the first substrate by the pressurized gas.

13. The substrate bonding apparatus of claim 12, wherein a second distance by which each of the plurality of second gas discharge devices protrudes from a surface of the second bonding chuck is less than a first distance by which the first gas discharge device protrudes from the surface of the second bonding chuck.

14. The substrate bonding apparatus of claim 13, wherein the first distance and the second distance are 0 μm to 300 μm, and
wherein the first gas discharge port and the second gas discharge port are spaced at least 50 μm away from the outer surface of the second substrate.

15. The substrate bonding apparatus of claim 11, further comprising a pressure sensor adjacent to the first gas discharge device and embedded in a surface of the second bonding chuck, wherein the pressure sensor measures gas pressure of a cavity that is a space between the second substrate and a surface of the second bonding chuck.

16. The substrate bonding apparatus of claim 15, further comprising a gas control device, wherein the gas control device comprises a valve, and
wherein the pressurized gas flows into the gas control device from the cavity and the gas control device controls an amount of the pressurized gas flowing out of the gas control device from the cavity to control internal pressure of the cavity.

17. The substrate bonding apparatus of claim 11, further comprising a distance sensor adjacent to the first gas discharge device and embedded in a surface of the second bonding chuck, wherein the distance sensor measures a distance between the first location of the second substrate and a surface of the second bonding chuck.

18. The substrate bonding apparatus of claim 17, wherein, when a third height that is a measured value of a distance between the second substrate and the second bonding chuck from the distance sensor is ae largest value during a bonding process, the controller controls the pressurized gas to be discharged from the plurality of second gas discharge devices, and
wherein the largest value of the third height during a bonding process is a distance between the second substrate and the second bonding chuck from the distance sensor when the first substrate contacts the second substrate at one contact point.

19. The substrate bonding apparatus of claim 11, wherein the plurality of second gas discharge devices comprise three second gas discharge devices, and
wherein the three second gas discharge devices are apart from one another at 120° intervals in the second bonding chuck with respect to the first gas discharge device.

20. A substrate bonding for bonding a first substrate to a second substrate, the substrate bonding apparatus comprising:
a first bonding chuck configured to support the first substrate;
a second bonding chuck facing the first bonding chuck and configured to support the second substrate;
a gas discharge device including a pin actuator and a gas discharge pin provided through the first location of the second bonding chuck and configured to discharge pressurized gas to an outer surface of the second substrate;
a pressure sensor adjacent to the gas discharge device and embedded in a surface of the second bonding chuck;
a distance sensor adjacent to the gas discharge device and embedded in a surface of the second bonding chuck;
a gas supply unit including a gas storage tank, a gas pressurizing unit, and a gas supply valve and configured to supply pressurized gas to the gas discharge device; and
a controller configured to control the gas discharge device and the gas supply unit, wherein one or more areas of negative pressure for attaching the second substrate to the a surface of the second bonding chuck is provided, and the gas discharge device comprises a gas discharge port for discharging the pressurized gas toward an outer surface of the second substrate, wherein the pressurized gas comprises gas or air including one or more of nitrogen, argon, neon, and helium, wherein the controller controls movement of the gas discharge device with respect to the second bonding chuck, and a flow rate and pressure of the pressurized gas in the gas discharge device, wherein the controller controls the gas discharge device to move toward the second substrate causing deformation of the first location of the second substrate such that the gas discharge port does not contact an outer surface of the second substrate as the first location of the second substrate is deformed by the pressurized gas, wherein the pressure sensor measures gas pressure of a cavity that is a space between the second substrate and the surface of the second bonding chuck, which is generated when the gas discharge device discharges the pressurized gas, wherein the pin actuator is configured to move the gas discharge device relative to the second substrate, and the gas discharge device protrudes from a surface of the second bonding chuck in a range of greater than 0 μm to 300 μm to move relative to the second substrate, wherein the gas discharge port is spaced at least 50 μm away from the outer surface of the second substrate, and
wherein the distance sensor measures a vertical distance between the first location of the second substrate and a surface of the second bonding chuck.
